(19) United States
(12) Patent Application Publication
(10) Pub. No.: US 2014/0102516 A1
(43) Pub. Date: Apr. 17, 2014

(54) Circumferential Frame for Attachment to an Edge of a Photovoltaic Module

(71) Applicants: WEN-YU SUN, Taipei City (TW); HSIU-MIN HUANG, Taipei City (TW); WU-YEN SUN, Taipei City (TW); WU-TING SUN, Taipei City (TW)

(72) Inventors: WEN-YU SUN, Taipei City (TW); HSIU-MIN HUANG, Taipei City (TW); WU-YEN SUN, Taipei City (TW); WU-TING SUN, Taipei City (TW)

(21) Appl. No.: 13/651,477

(22) Filed: Oct. 15, 2012

(51) Int. Cl. H01L 31/048

(52) U.S. Cl. 136/251

(57) ABSTRACT

The present invention provides a circumferential frame for attachment to an edge of a photovoltaic module, which utilizes an adhesive method to achieve the attachment between the circumferential frame and the edge of the photovoltaic module without the aids of fastening means and such that the overall weight and size of the frame as well as the supporting stand can be reduced while the load bearing of houses can be reduced and photovoltaic modules of greater sizes or surface areas can be installed for practical purposes.

### TECHNICAL FIELD OF THE INVENTION

The present invention is related to a circumferential frame for attachment to an edge of a photovoltaic module and provided for securement thereon as well as to a photovoltaic module with such circumferential frame attached thereon.

### DESCRIPTION OF THE PRIOR ART

Currently, “photovoltaic modules with frame” available in the market are mostly silicon type of photovoltaic modules having an outer frame made of aluminum alloys clamping onto glass, EVA film, solar panel, EVA film and TPT backboard therebetween, which too mostly adopt the methods of aluminum alloy press-fit or rear fastening to be secured onto solar supporting stands.

However, since the attachment between the outer frame and the photovoltaic module utilizes fastening means penetrating the outer frame to press against the photovoltaic module in order to achieve the securement thereof, such method is time-consuming and is likely to cause damages to the photovoltaic module.

Furthermore, during the actual installation of the module, the combination including the frame of the photovoltaic module attached to supporting stand is of a heavy weight and a bulky size occupying significant amount of space, which is not optimal to high-rise city buildings with limited roof surface area and load bearing capacity that affects the sunshine receiving area of the photovoltaic module.

### SUMMARY OF THE INVENTION

The present invention provides a circumferential frame for attachment to an edge of a photovoltaic module, which utilizes an adhesive method for attaching the circumferential frame to the edge of said photovoltaic module such that fastening means can be avoided and such that the size occupied and weight of the frame as well as the supporting apparatus can be reduced.

To achieve the abovementioned purposes of the present invention, a circumferential frame for attachment to an edge of a photovoltaic module is advantageously provided, wherein said attachment utilizes an adhesive method for attaching an edge of the photovoltaic module such that the volume and weight of fastening means can be subtracted from the total size and weight thereof in order to reduce the load bearing of the house and to facilitate the installation of photovoltaic modules of greater surface areas as well as to increase the overall power generated.

In addition and according to the above, wherein said circumferential edge can be of a C-shape such that a stable clamping can be achieved as a merit thereof.

Furthermore, an edge of said solar panel protrudes outward from said transparent glass and said backboard such that said solar panel is inserted into a slot provided on said circumferential frame; and said transparent glass and said backboard abut to an upper edge and a lower edge of said circumferential frame respectively. Therefore, the thickness of the circumferential frame is thinner and the overall thickness of the module is reduced.

In addition, the transparent glass is aligned with said upper edge of said circumferential frame, and said backboard is aligned with said lower edge of said circumferential frame.

Preferably, a lower side of said circumferential edge is longer in length than an upper side thereof such that the load bearing of the circumferential frame can be increased without reducing the sunshine surface area of the solar panel.

Also, the circumferential edge can be a flat slat.

Preferably, an inner side of said circumferential edge is indented inward such that the load bearing to withstand the solar panel can be increased.

In addition, said circumferential edge can be of an L-shape such that the module is facilitated for installation and is of increased supporting areas.

The present invention further provides a circumferential frame for attachment to an edge of a photovoltaic module, comprising a photovoltaic module and at least two circumferential frames. The photovoltaic module comprises a transparent glass, a solar panel and a backboard; wherein said transparent glass is disposed on a top of said solar panel and said backboard is disposed on a bottom of said solar panel; and the circumferential frames are attached to said edge of said photovoltaic module by means of adhesion onto two opposing sides of said edge of said photovoltaic module.

The present invention further provides a supporting apparatus for a photovoltaic module with a circumferential frame attached thereon, comprising two tracks; and wherein said two tracks are arranged on opposing sides and are provided for guiding said photovoltaic module attached with said circumferential frame to slide therein such that the installation thereof is facilitated.

### BRIEF DESCRIPTION OF THE DRAWINGS

FIGS. 1 to 7 are cross sectional views of a circumferential frame of the present invention with a C-shape;

FIGS. 8 to 11 are cross sectional views of a circumferential frame of the present invention as a vertical flat slat;

FIGS. 12 to 13 are cross sectional views of a circumferential frame of the present invention with an L-shape;

FIG. 14 is a top view of two circumferential frame attachments of the present invention;

FIG. 15 is an illustration showing the photovoltaic module S with two circumferential frames attached thereon in FIG. 14 being inserted into the tracks; and

FIG. 16 is a side view of FIG. 15.

### DETAILED DESCRIPTION OF THE PREFERRED EMBODIMENTS

It shall be understood that the term of photovoltaic module used in the following description of the embodiments of the present invention includes “a photovoltaic module or a photovoltaic board” or any constructions in the form to a person skilled in the art capable of recognizing it as being similar to a module or board.

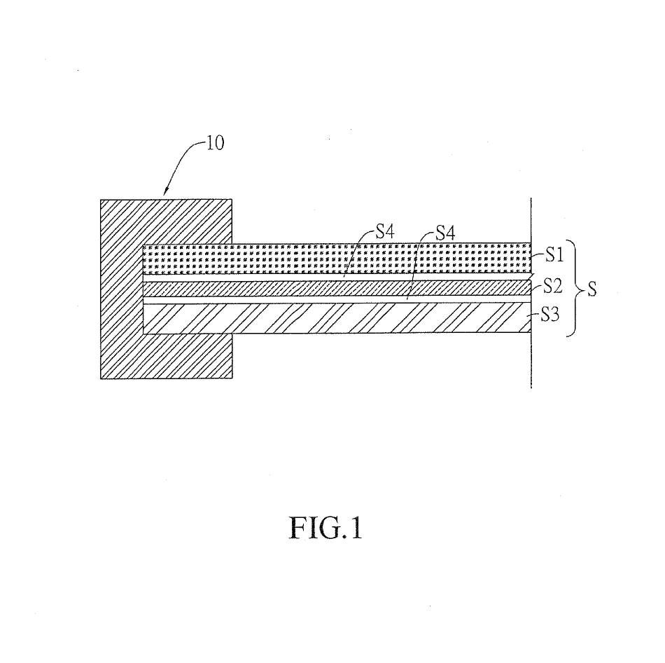

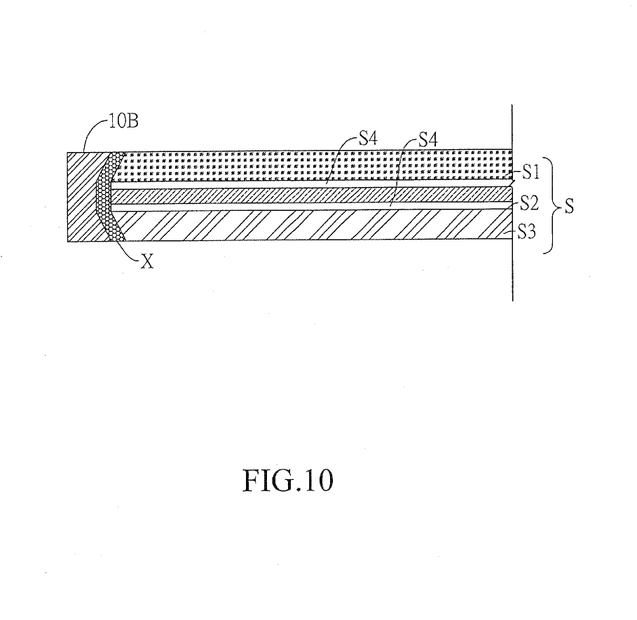

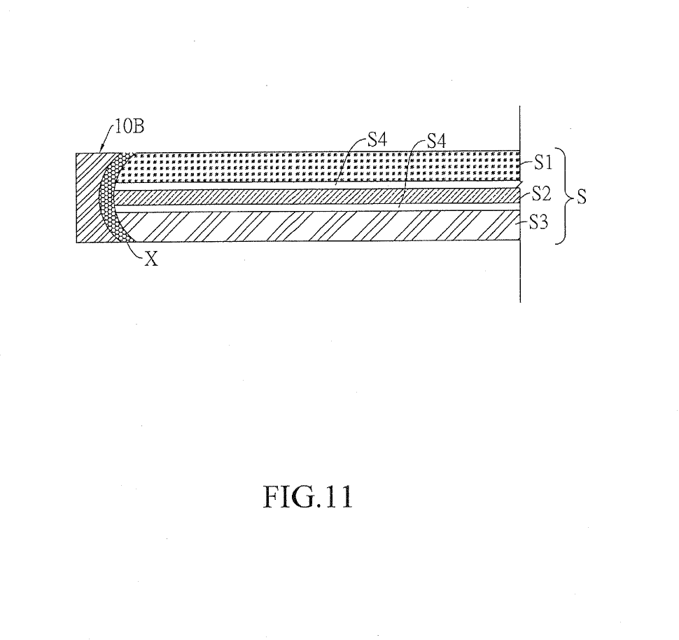

As shown in FIGS. 1 to 13, the present invention provides a circumferential frame 10 for attachment to an edge of a photovoltaic module S, and wherein the attachment of the circumferential frame 10 utilizes an adhesive method. Therefore, the embodiment of the circumferential frame 10 adhered onto the photovoltaic module S requires no fastening means for assembly such that the overall weight of the module is reduced and the manufacturing processes thereof is too advantageously simplified.

The following provides further details of the extended configurations of the circumferential frame 10. Accordingly, the photovoltaic module S comprises a transparent glass S1, a solar panel S2 and a backboard S3. In addition, an EVA film S4 is used for adhering the transparent glass S1 with the solar panel S2 as well as for adhering the solar panel S2 with the backboard S3.

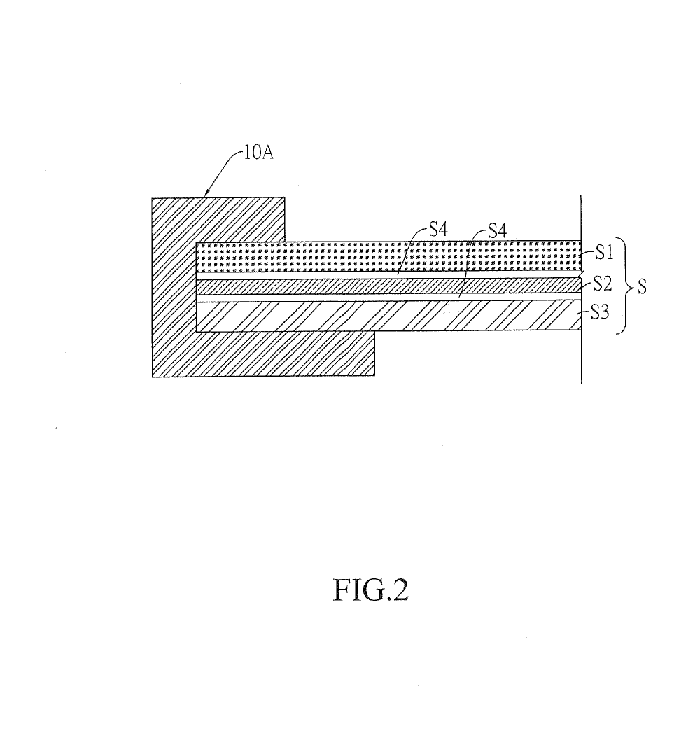

As shown by the cross sectional view of FIG. 1, the circumferential frame 10 is of a C-shape such that the edge of the photovoltaic module S can be adhered to the internal of the slots in order to achieve the effect of a stable clamping of the module. Alternatively, as shown by the cross sectional view of FIG. 2, the circumferential frame 10A is also of a C-shape and the bottom portion of the circumferential frame 10 can be further extended forward such that greater supports are being provided to the photovoltaic module S.

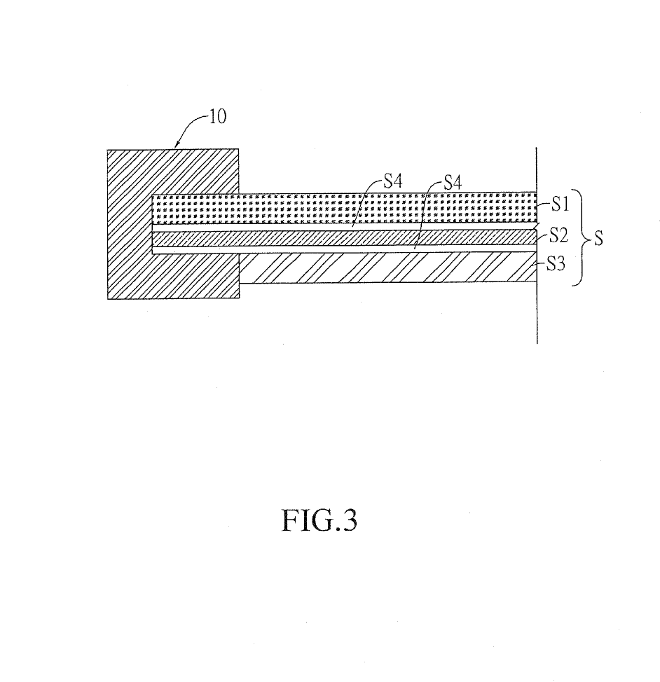

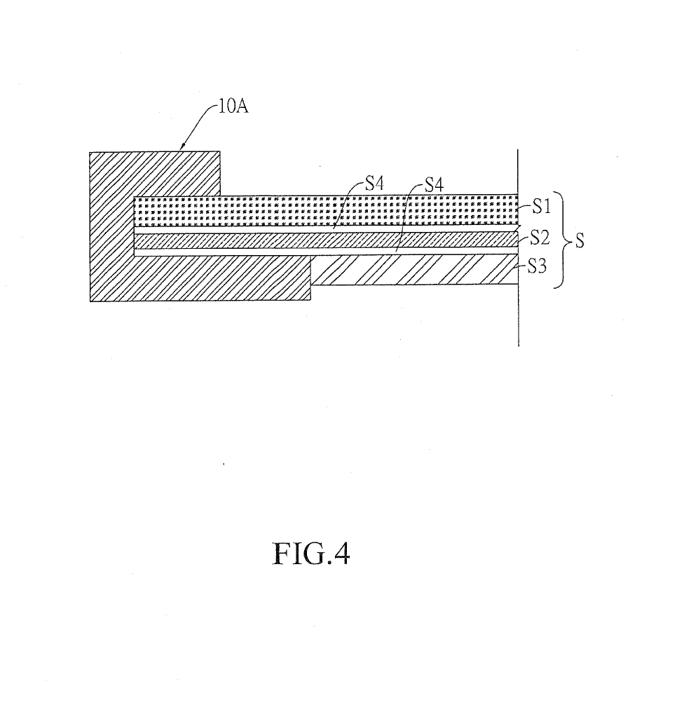

Refer now to the cross sectional views shown in FIGS. 3 and 4. Accordingly, the lower front end of the circumferential frame 10 and 10A abuts the backboard S3, and additionally, the transparent glass S1 of the photovoltaic module S and the solar panel S2 are inserted into the slots of the circumferential frame 10 for further adhesion thereon such that the overall height (thickness) can be reduced to facilitate the transportation of the module.

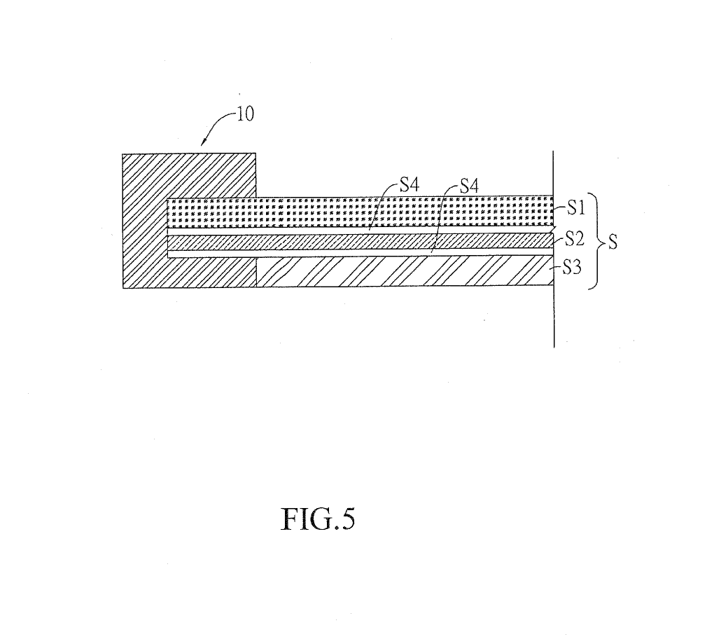

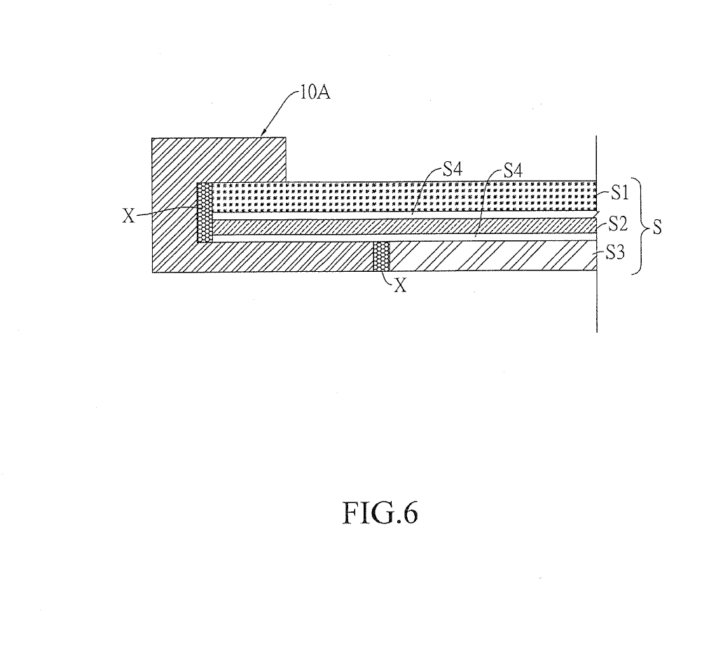

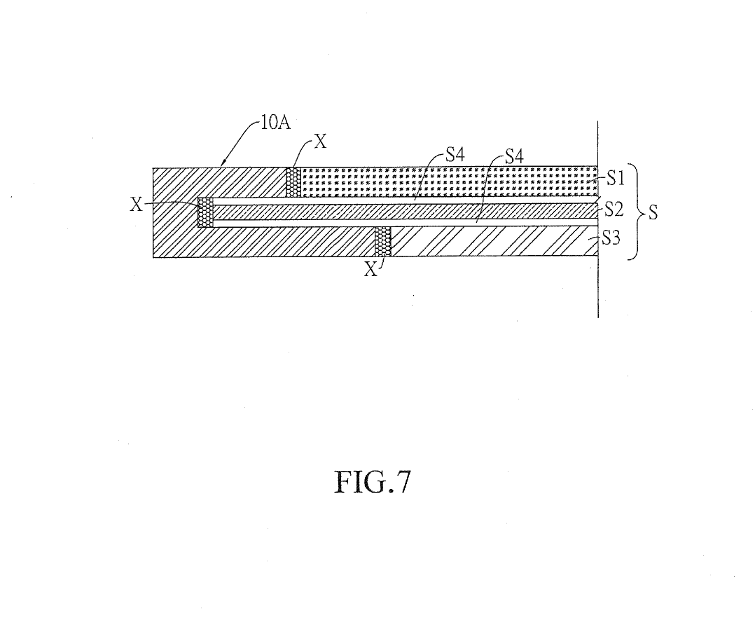

As shown in FIGS. 5 and 6, the lower front end of the circumferential frame 10 and 10A abuts and is aligned with the backboard S3 such that the overall height can be further reduced. In addition, as shown in FIG. 7, the upper front end of the circumferential frame 10A abuts and is aligned with the transparent glass S1 and the lower front end thereof abuts and is aligned with the backboard S3 such that the module can be constructed to be even thinner.

Furthermore, to further understand the adhesive method of this embodiment of the present invention, areas for placing adhesive gel X can be specified by markings as shown in FIGS. 6 to 13. However, it can be understood that the coated area and its thickness ratio do not need to be restricted to be of any particular shapes or forms.

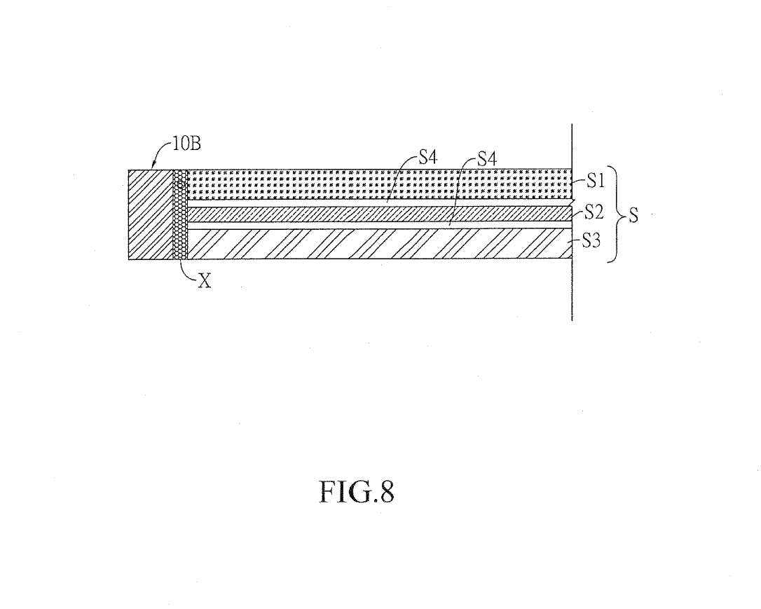

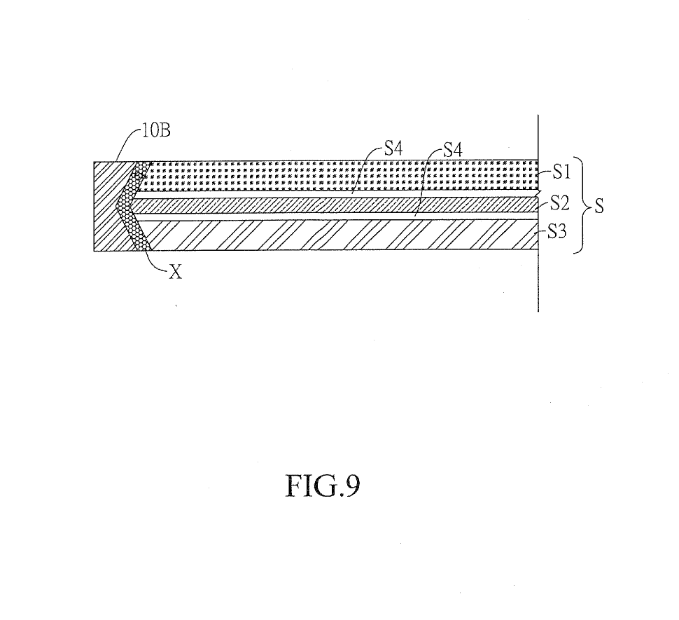

As shown in FIG. 8, the circumferential frame 10B is a vertical flat slat; and wherein the upper and lower two ends thereof are aligned with the photovoltaic module S such that it is of the merits of being convenient for assembly and is of a smaller size. In addition, as shown in FIGS. 9 to 11, the circumferential frame 10B comprises an inner side with an inward indent configured to be of any shapes and the edge of the photovoltaic module adapts the shape of the cutting correspondingly such that the contact area of the circumferential frame 10 is increased and the adhesiveness between the circumferential frame 10B and the photovoltaic module is also enhanced.

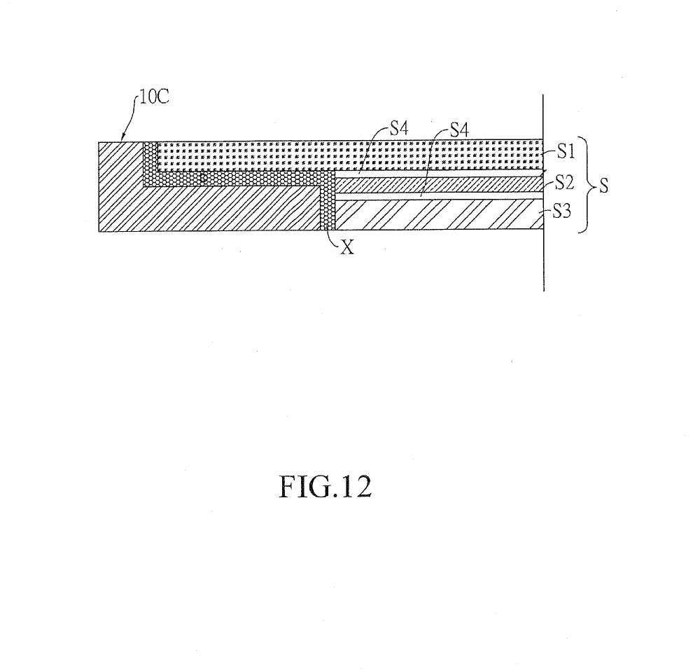

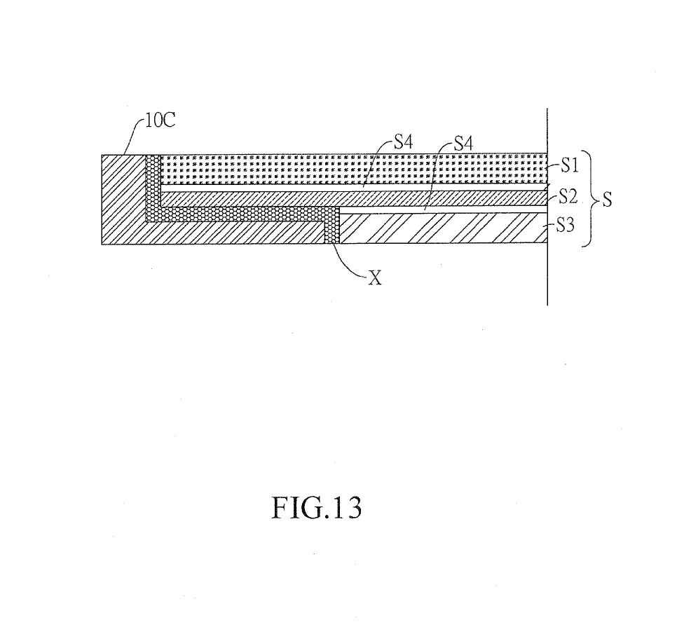

Furthermore, as shown in FIGS. 12 and 13, the circumferential frame 10C can be of an L-shape; wherein the top and the bottom thereof can be aligned with the top and bottom of the photovoltaic module S. Also, as shown in FIG. 12, the solar panel S2 and the backboard S3 are adhered to the rear end of the circumferential frame 10C, or alternatively, the transparent glass S1 and the solar panel S2 can be adhered to the vertical surface of the circumferential frame 10C.

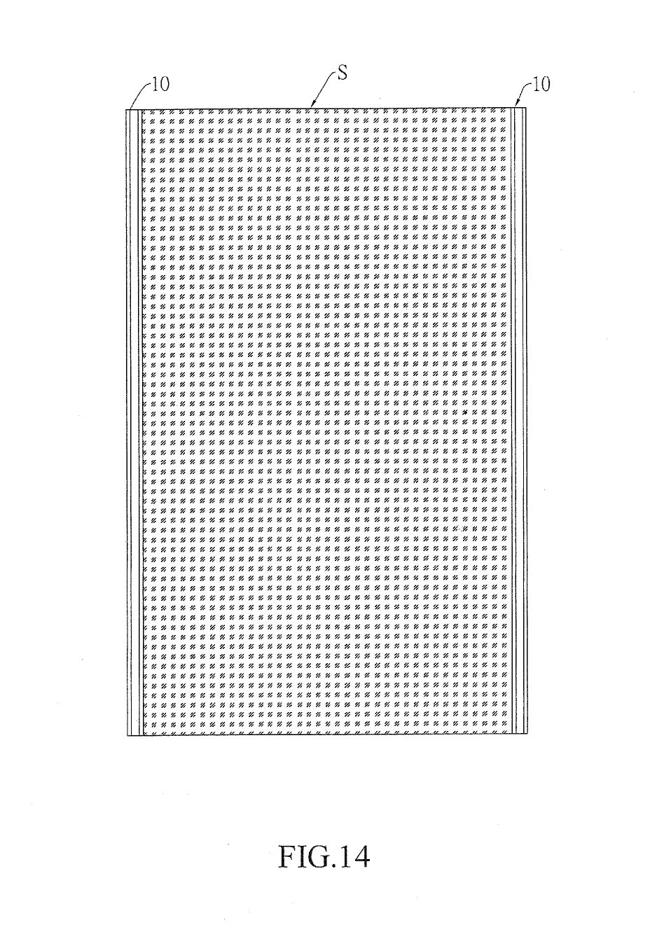

FIG. 14 shows a top view of the photovoltaic module S with the circumferential frame 10 attached thereon. Accordingly, the two circumferential frames 10 are adhered onto the edge of the photovoltaic module S and are provided on two opposing sides of the edge of the photovoltaic module S such that protections to the module as well as the assembly thereof can be achieved and facilitated.

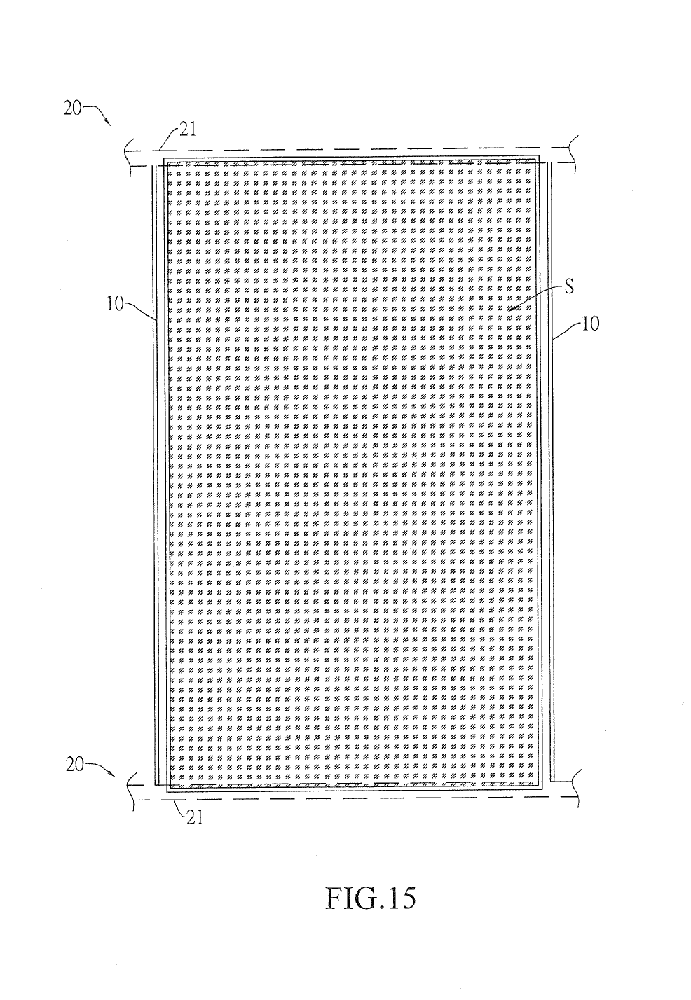

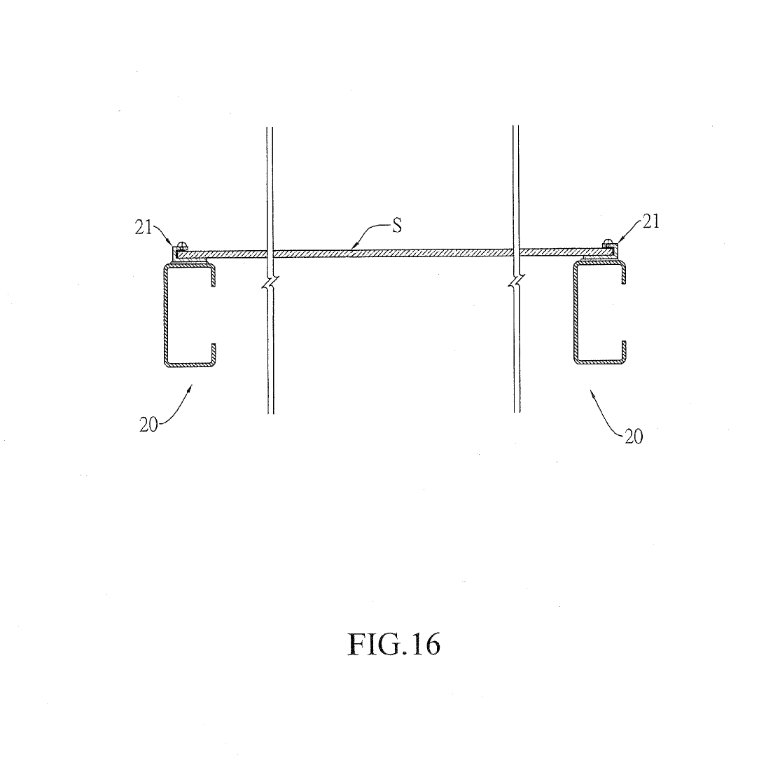

In addition, as shown in FIGS. 15 and 16, a supporting apparatus 20 is provided for the two photovoltaic modules S. The supporting apparatus 20 comprises at least two tracks 21; wherein the two tracks 20 are on opposing sides corresponding to the other two sides, free from the attachment with the circumferential frame 10, of the abovementioned photovoltaic module with the circumferential frame attached thereon. Therefore, the photovoltaic module with the circumferential frame attached thereon can be guided to be assembled onto the supporting apparatus 20 and to slide therein such that the circumference of the photovoltaic module S can be completely covered, the assembly and installation thereof are facilitated, the tracks 21 are incorporated therein and the size and weight thereof are greatly reduced as a whole.

What is claimed is:

1. A circumferential frame for attachment to an edge of a photovoltaic module, wherein said attachment utilizes an adhesive method for attaching said edge of said photovoltaic module.

2. The circumferential frame for attachment to an edge of a photovoltaic module according to claim 1, wherein said circumferential edge is of a C-shape.

3. The circumferential frame for attachment to an edge of a photovoltaic module according to claim 2, wherein said photovoltaic module comprises a transparent glass, a solar panel and a backboard; an edge of said solar panel protrudes outward from said transparent glass and said backboard such that said solar panel is inserted into a slot provided on said circumferential frame; and said transparent glass and said backboard abut to an upper edge and a lower edge of said circumferential frame respectively.

4. The circumferential frame for attachment to an edge of a photovoltaic module according to claim 3, wherein said transparent glass is aligned with said upper edge of said circumferential frame, and said backboard is aligned with said lower edge of said circumferential frame.

5. The circumferential frame for attachment to an edge of a photovoltaic module according to claim 2, wherein said photovoltaic module comprises a transparent glass, a solar panel and a backboard; said transparent glass and an edge of said solar panel protrude outward from said transparent glass and said backboard such that said transparent glass and said solar panel are inserted into a slot provided on said circumferential frame; and said backboard abuts to a lower edge of said circumferential frame respectively.

6. The circumferential frame for attachment to an edge of a photovoltaic module according to claim 5, wherein said backboard is aligned with said lower edge of said circumferential frame.

7. The circumferential frame for attachment to an edge of a photovoltaic module according to claim 2, wherein said photovoltaic module comprises a transparent glass, a solar panel and a backboard; and said transparent glass, said solar panel and said backboard are inserted into a slot provided on said circumferential frame.

8. The circumferential frame for attachment to an edge of a photovoltaic module according to claim 2, wherein a lower side of said circumferential edge is longer in length than an upper side thereof.

9. The circumferential frame for attachment to an edge of a photovoltaic module according to claim 1, wherein said circumferential edge is a flat slat.

10. The circumferential frame for attachment to an edge of a photovoltaic module according to claim 1, wherein an inner side of said circumferential edge is indented inward.

11. The circumferential frame for attachment to an edge of a photovoltaic module according to claim 1, wherein said circumferential edge is of an L-shape.

12. A circumferential frame for attachment to an edge of a photovoltaic module, comprising:
a photovoltaic module comprising a transparent glass, a solar panel and a backboard; wherein said transparent glass is disposed on a top of said solar panel and said backboard is disposed on a bottom of said solar panel; and
at least two circumferential frames attached to said edge of said photovoltaic module by means of adhesion onto two opposing sides of said edge of said photovoltaic module.

13. A supporting apparatus for a photovoltaic module with a circumferential frame attached thereon, comprising two tracks; wherein said two tracks are arranged on opposing sides and are provided for guiding said photovoltaic module attached with said circumferential frame as claimed in claim 9 to slide therein.
